(19) United States
(12) Patent Application Publication
(10) Pub. No.: US 2015/0338467 A1
(43) Pub. Date: Nov. 26, 2015

(54) Method and Device for Measuring State of Charge of Mobile Terminal

(71) Applicant: ST-Ericsson SA, Plan-les-Ouates (CH)

(72) Inventors: Li Yuan LIU, Beijing (CN); Lin WANG, Beijing (CN)

(21) Appl. No.: 14/758,628

(22) PCT Filed: Jan. 30, 2013
(86) PCT No.: PCT/CN2013/071139

§ 371 Date: Jun. 30, 2015

(51) Int. Cl. G01R 31/36; H04W 52/02

(52) U.S. Cl. CPC G01R 31/3624; H04W 52/0251; G01R 31/3648

(57) ABSTRACT

The present invention relates to the field of battery measurement for a mobile terminal, and provides a method and a device for measuring state of charge (SoC) of a mobile terminal The method comprises: measuring, after the mobile terminal enters a sleep/idle mode, battery parameters of the mobile terminal in accordance with a predetermined measurement period; filtering, when the mobile terminal exits the sleep/idle mode, the measured battery parameters and storing the filtered battery parameters; and acquiring state of charge of the mobile terminal in accordance with the stored battery parameters. According to the technical solution of the present invention, the battery power of the mobile terminal can be measured and the process of the battery power consumption can be calculated accurately.

### TECHNICAL FIELD

The present invention relates to the field of battery measurement for a mobile terminal, in particular to a method and a device for measuring state of charge of a mobile terminal.

### BACKGROUND

State of charge (SoC) of a mobile terminal is a very important indicator of a mobile terminal user, and how to estimate the SoC quickly and accurately through software and hardware remains a tough target. In the prior art, a period calculation algorithm is mainly used to detect the SoC of the mobile terminal and usually three primary parameters are used to calculate the SoC, i.e., VBAT (voltage of battery), IBAT (working current of battery that matches VBAT) and Temperature (temperature of battery). When a system of the mobile terminal is in an active mode, the battery management software can periodically update these parameters, and update the SoC of the battery via the period calculation algorithm based on these parameters.

However, when the system of the mobile terminal is in a sleep or idle mode, there is not an algorithm or a precise solution in the prior art to detect the SoC. When the system is awoken from the sleep or Idle mode, the SoC displayed on an existing mobile terminal is still that stored when the mobile terminal enters the sleep or idle mode. At this time, the differences maybe happen between the actual SoC of the mobile terminal and the displayed SoC. As a result, the accuracy of the SoC measurement decreases. Moreover, it is impossible for the existing solution to obtain the process or curve of the battery power consumption of the mobile terminal.

### SUMMARY

An object of the present invention is to provide a method and a device for measuring SoC of a mobile terminal, so as to measure the battery power consumption of the mobile terminal and to calculate the process of the battery power consumption accurately.

To achieve the above-mentioned object, the present invention provides a method for measuring SoC of a mobile terminal, comprising:

measuring, after the mobile terminal enters a sleep/idle mode, battery parameters of the mobile terminal in accordance with a predetermined measurement period;

filtering, when the mobile terminal exits the sleep/idle mode, the measured battery parameters and storing the filtered battery parameters; and

acquiring SoC of the mobile terminal in accordance with the stored battery parameters.

Prior to measuring battery parameters of the mobile terminal in accordance with a predetermined measurement period, the method further comprises: receiving a hardware indicator signal that indicates the mobile terminal to enter or exit the sleep/idle mode.

In the method, the measurement period is not greater than one third of the minimum paging duration of the mobile terminal.

Further, in the method, the battery parameters include working voltage values and working current values of the battery. The step of filtering the measured battery parameters includes:

removing the working voltage values less than a predetermined voltage threshold and the working current values greater than a predetermined current threshold from the measured battery parameters; and

storing the working voltage values not less than the predetermined voltage threshold and the working current values not greater than the predetermined current, threshold.

In the method, the step of acquiring SoC of the mobile terminal in accordance with the stored battery parameters includes: calculating the battery power in accordance with the stored battery parameters when the mobile terminal exits the sleep/idle mode, and acquiring a curve of the battery power consumption when the mobile terminal is in the sleep/idle mode.

In the method, the step of calculating the battery power in accordance with the stored battery parameters when the mobile terminal exits the sleep/idle mode includes: calculating the battery power in accordance with the working voltage value and working current value stored last time when the mobile terminal exits the sleep/idle mode.

In the method, the step of acquiring a curve of the battery power consumption when the mobile terminal is in the sleep/idle mode includes: calculating a curve of the battery power consumption in accordance with all of the stored working voltage values and working current values when the mobile terminal is in the sleep/idle mode.

The present invention further provides a device for measuring SoC of a mobile terminal, comprising:

a measuring module, configured to measure, after the mobile terminal enters a sleep/idle mode, battery parameters of the mobile terminal in accordance with a predetermined measurement period;

a storing module, configured to filter, when the mobile terminal exits the sleep/idle mode, the measured battery parameters and store the filtered battery parameters; and

a calculating module, configured to acquire SoC of the mobile terminal in accordance with the stored battery parameters.

The device further comprises:

a receiving module, configured to receive a hardware indicator signal that indicates the mobile terminal to enter the sleep/idle mode, wherein

the measuring module, configured to, after the receiving module receives the hardware indicator signal that indicates the mobile terminal, to enter the sleep/idle mode, measure a plurality of battery parameters of the mobile terminal simultaneously in accordance with the predetermined measurement period.

The measurement period is not greater than one third of the minimum paging duration of the mobile terminal.

The battery parameters include working voltage values and working current values of the battery, and the storing module comprises:

a filtering sub-module, configured to remove the working voltage values less than a predetermined voltage threshold and the working current, values greater than a predetermined current threshold from the measured battery parameters; and

a storing submodule, configured to store the working voltage values not less than the predetermined voltage threshold and the working current values not greater than the predetermined current threshold.

The calculating module comprises:

a first calculating submodule, configured to calculate the battery power in accordance with the stored battery parameters when the mobile terminal exits the sleep/idle mode; and

a second calculating submodule, configured to acquire a curve of battery power consumption when the mobile terminal is in the sleep/idle mode.

The first calculating submodule is specifically configured to calculate the battery power in accordance with the working voltage value and the working current value stored last time when the mobile terminal exits the sleep/idle mode.

The second calculating submodule is specifically configured to calculate a curve of battery power consumption of the battery in accordance with all of the stored working voltage values and working current values when the mobile terminal is in the sleep/idle mode.

The present invention has the following advantages.

After the mobile terminal enters the sleep/idle mode, the battery parameters of the mobile terminal are measured in accordance with the predetermined measurement period, and when the mobile terminal exits the sleep/idle mode, the measured battery parameters are filtered and the valid battery parameters are stored. As a result, it is able to calculate the battery power of the mobile terminal accurately in accordance with the stored valid battery parameters, and to acquire the process of the battery power consumption simultaneously when the mobile terminal is in the sleep/idle mode.

### BRIEF DESCRIPTION OF THE DRAWINGS

FIG. 1 is a flow chart of a method for measuring SoC of a mobile terminal according to embodiments of the present invention;

FIG. 2 is a block diagram, of a device for measuring SoC of a mobile terminal according to embodiments of the present invention;

FIG. 3 is a schematic view showing the working voltage and working current of the mobile terminal in a sleep/idle mode;

FIG. 4 is a schematic view showing the measurement of the working voltage and working current of the mobile terminal in the sleep/idle mode according to embodiments of the present invention; and

FIG. 5 is a specific flow chart, of a method for measuring SoC of a mobile terminal according to embodiments of the present invention.

### DETAILED DESCRIPTION

To make the technical problems to be solved by the present invention, the technical solutions and the advantages more apparent, the present invention will be described hereinafter in conjunction with the drawings and the embodiments.

The present invention provides a method and a device for measuring SoC of a mobile terminal so as to measure the battery power of the mobile terminal and calculate the process of the battery power consumption accurately.

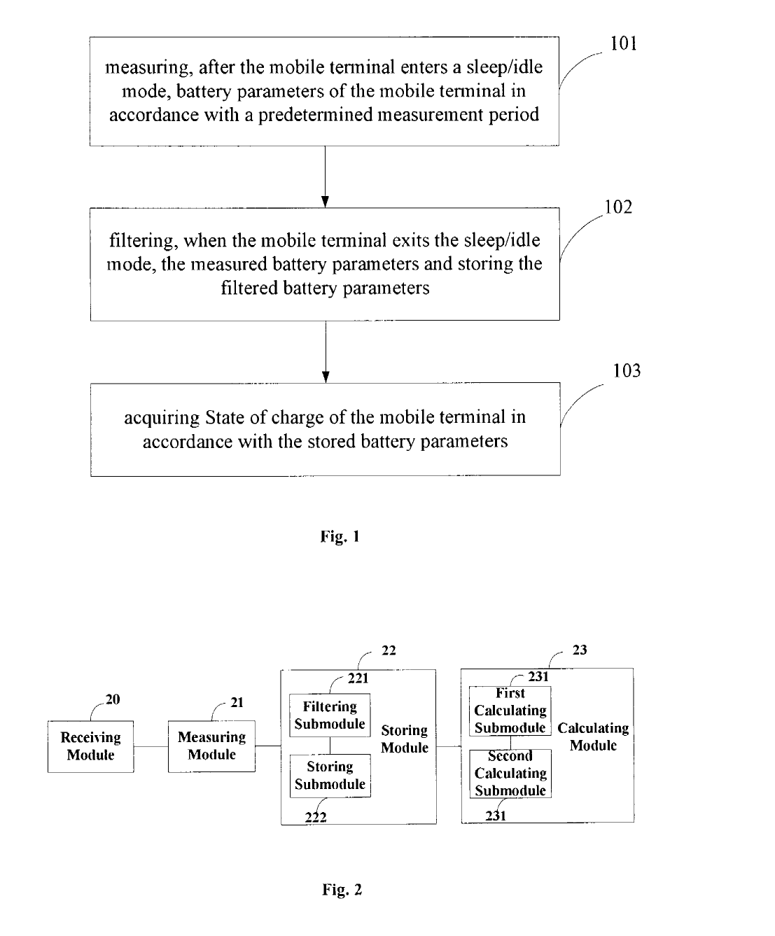

As shown in FIG. 1, which is a flow chart of a method for measuring SoC of a mobile terminal according to embodiments of the present invention, the method comprises:

Step 101: measuring, after the mobile terminal enters a sleep/idle mode, battery parameters of the mobile terminal in accordance with a predetermined measurement period;

Step 102: filtering, when the mobile terminal exits the sleep/idle mode, the measured battery parameters and storing the filtered battery parameters; and

Step 103: acquiring SoC of the mobile terminal in accordance with the stored battery parameters.

According to another embodiment of the present invention, prior to Step 101, the method further comprises receiving a hardware indicator signal that indicates the mobile terminal to enter or exit the sleep/idle mode.

In Step 101, the measurement period is not greater than one third of the minimum paging duration of the mobile terminal.

The battery parameters include working voltage values and working current valises of the battery. To be specific, Step 102 includes:

removing the working voltage values less than a predetermined voltage threshold and the working current values greater than a predetermined current threshold from the measured battery parameters; and

storing the working voltage values not less than the predetermined voltage threshold and the working current values not greater than the predetermined current threshold.

Step 103 includes: calculating the battery power in accordance with the stored battery parameters when the mobile terminal exits the sleep/idle mode, and acquiring a curve of battery power consumption, when the mobile terminal is in the sleep/idle mode.

To be specific, Step 103 includes: calculating the battery power in accordance with the working voltage value and the working current value stored last time when the mobile terminal exits the sleep/idle mode, and calculating a curve of battery power consumption in accordance with all of the stored working voltage values and working current values when the mobile terminal is in the sleep/idle mode.

According to the method for measuring SoC of a mobile terminal of the present invention, after the mobile terminal enters the sleep/idle mode, the battery parameters of the mobile terminal are measured in accordance with the predetermined measurement period, and after the mobile terminal exits the sleep/idle mode, the measured battery parameters are filtered and the valid battery parameters are stored. As a result, it is able to accurately calculate the battery power of the mobile terminal in accordance with the stored valid battery parameters, and to acquire the process of the battery power consumption when the mobile terminal is in the sleep/idle mode simultaneously.

As shown in FIG. 2, which is a block diagram showing a device for measuring SoC of a mobile terminal according to embodiments of the present invention, the device comprises:

a measuring module 21, configured to, after the mobile terminal enters a sleep/idle mode, measure battery parameters of the mobile terminal in accordance with a predetermined measurement period;

a storing module 22, configured to filter the measured battery parameters and store the filtered battery parameters when the mobile terminal exits the sleep/idle mode; and

a calculating module 23, configured, to acquire SoC of the mobile terminal in accordance with the stored battery parameters.

The device may further comprises:

a receiving module 20, configured to receive a hardware indicator signal that indicates the mobile terminal to enter the sleep/idle mode, wherein

the measuring module 21, specifically configured to, after the receiving module 20 receives the hardware indicator signal that indicates the mobile terminal to enter the sleep/idle mode, measure a plurality of battery parameters of the mobile terminal in accordance with the predetermined measurement period simultaneously.

In the device, the measurement period is not greater than one third of the minimum paging duration of the mobile terminal.

The battery parameters include working voltage values and working current values. The storing module 22 may further includes:

a filtering submodule 221, configured to remove the working voltage values less than a predetermined, voltage threshold and the working current values greater than a predetermined current threshold from the measured battery parameters; and

a storing submodule 222, configured to store the working voltage values not less than the predetermined voltage threshold and the working current values not greater than the predetermined current threshold.

In the device, the calculating module 23 may further includes:

a first calculating submodule 231, configured to calculate the battery power in accordance with the stored battery parameters when the mobile terminal exits the sleep/idle mode; and

a second calculating submode 232, configured to acquire a curve of battery power consumption when the mobile terminal is in the sleep/idle mode.

The first calculating submodule 231, specifically configured to calculate the battery power in accordance with the working voltage value and the working current value stored last time when the mobile terminal exits the sleep/idle mode; and

the second calculating sub-module 232, specifically configured to calculate a curve of battery power consumption in accordance with all of the stored working voltage values and working current values when the mobile terminal is in the sleep/idle mode.

According to the device for measuring SoC of a mobile terminal of the present invention, after the mobile terminal enters the sleep/idle mode, the battery parameters of the mobile terminal are measured in accordance with the predetermined measurement period, and after the mobile terminal exits the sleep/idle mode, the measured battery parameters are filtered and the valid battery parameters are stored. As a result, it is able to accurately calculate the battery power of the mobile terminal in accordance with the stored valid battery parameters, and to acquire the process of the battery power consumption when the mobile terminal is in the sleep/idle mode simultaneously.

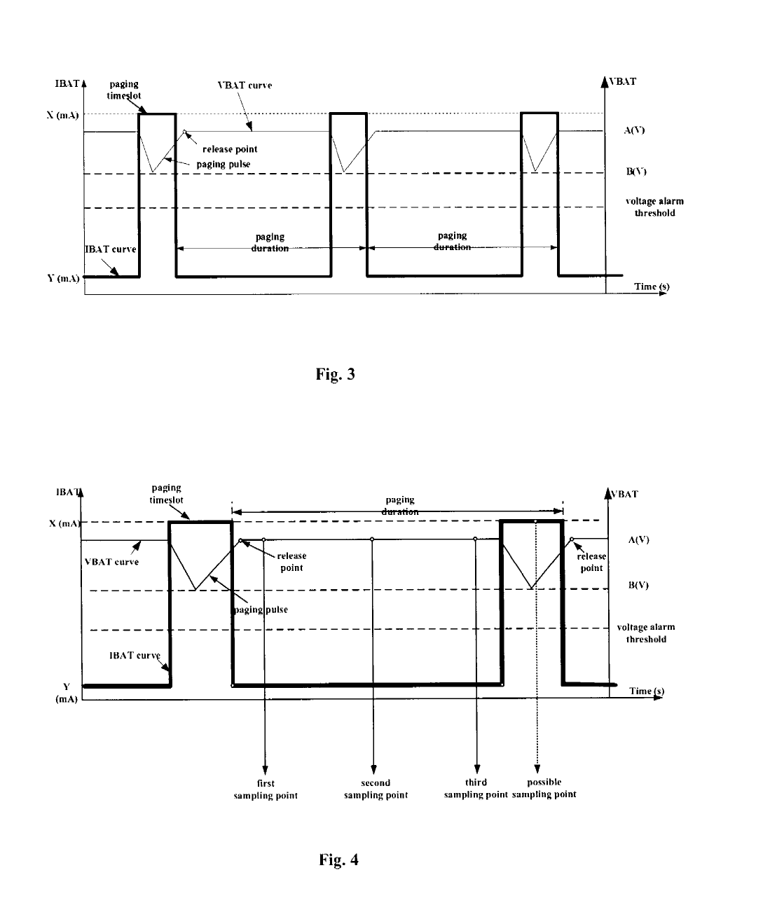

The method and device for measuring SoC of a mobile terminal according to the present invention will be described hereinafter in conjunction with FIGS. 3-5 and embodiments of the present invention.

The mobile terminal includes an AP (Application Processor) and other modules connected to the AP, e.g., Modem, Bluetooth or WLAN (Wireless Local Area Networks) modules. When the AP is in an active state, the battery power consumption of the mobile terminal is in a stable state. When the AP enters a sleep/idle mode, in order to match the AP state, the other modules connected thereto will also enter the sleep/idle mode. As a result, the battery power consumption of the mobile terminal will decrease, and merely low battery power consumption is required for the whole system of the mobile terminal (e.g., 2.5 mA).

In the prior art, there exists no solution capable of detecting the SoC of the mobile terminal when the mobile terminal is in the sleep or idle mode. When the mobile terminal enters the sleep or idle mode, it requires no longer measuring and updating the SoC of the mobile terminal. When the mobile terminal is awoken after it is in the sleep/idle mode for a period of time, the battery power displayed on the mobile terminal is still that stored before the mobile terminal enters the sleep or idle mode. As a result, the power measurement accuracy will decrease, and especially, there exists a relatively great difference between the actual battery power and the displayed battery power when the mobile terminal is in the sleep or idle mode for a long period of time.

In order to solve the above-mentioned problem, the present invention provides a method and a device for measuring SoC of a mobile terminal, so as to acquire the SoC when the mobile terminal is in a sleep or idle mode, and thereby to accurately measure the battery power consumption of the mobile terminal.

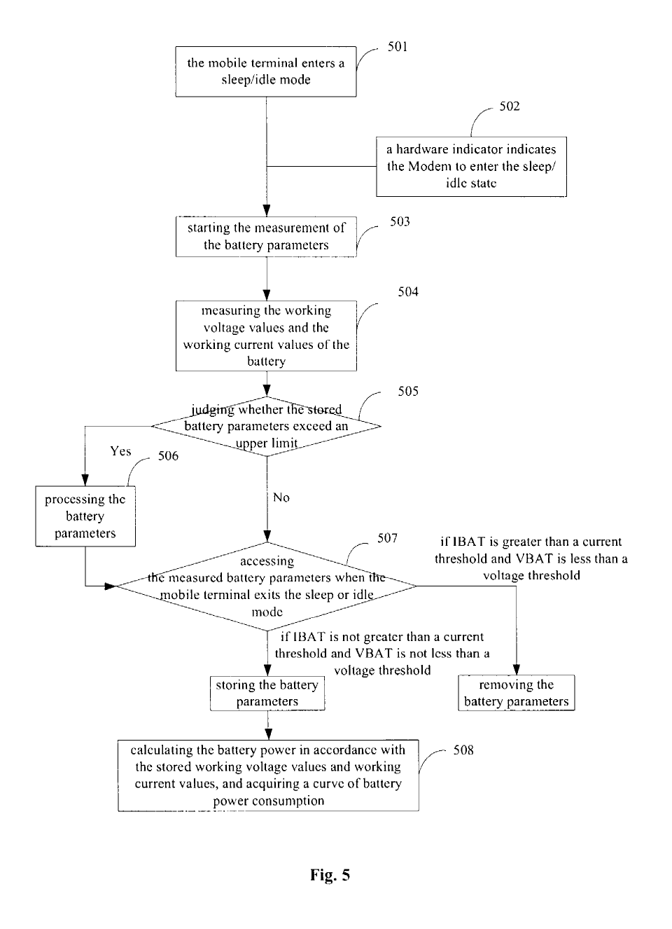

The technical solution of the present invention is described hereinafter by taking Modem that is connected to the AP as an example. As shown in FIG. 5, the method for measuring SoC of a mobile terminal comprises the following steps.

Step 501: the mobile terminal enters a sleep/idle mode.

As shown in FIG. 3, when a system of the mobile terminal is in the sleep/idle mode, working voltage and working current of the battery will maintain a stable state. When paging is performed by the Modem (according to the 3GPP specification, Modem still needs to keep updating the base station information when the system of the mobile terminal enters the sleep or idle mode, and this process is called as paging), a pulse current is generated by the battery of the mobile terminal, and this pulse current is higher than the power requirement when the system power is in a sleep or idle mode, e.g., up to 50-60 mA. If the SoC measurement is performed at this time, a value of the measurement is incredible. This is because the voltage of the battery will decrease remarkably at this time. After the pulse current is generated for a period of time, the battery voltage is released at a release point, and then returns to be in a stable state.

Step 502: a hardware indicator indicates the Modem to enter the sleep/idle state.

According to embodiments of the present invention, the measurement may be triggered in accordance with, the received hardware indicator signal. The AP is provided with a hardware indicator at the Modem side for indicating the transition of the sleep, idle and wakeup states. When the hardware indicator indicates the Modem to enter the sleep or idle state, the SoC measurement is started, and once it indicates that the Modem is to be awoken, the measurement is ended.

Step 503: the measurement of the battery parameters is started.

Even if the mobile terminal is in the sleep or idle mode, a power measurement operational module (e.g., a PRCMU on a ST-Bricsson platform) that works in an always-on power supply can still measure the SoC periodically. In this embodiment, after a signal is received from the hardware indicator for indicating the Modem to enter the sleep or idle mode, it starts to sample the working voltage and working current of the battery of the mobile terminal, simultaneously in accordance with a predetermined measurement period. Further, the measurement may also be triggered by a software protocol between the AP and the Modem.

The measurement period is determined upon a paging duration of the Modem, as shown in FIG. 4. The Modem has a short paging timeslot, and the measurement values obtained within this paging timeslot is invalid. It should make sure that the measurement is taken three times during a single paging duration, so as to obtain at least two valid sampling points, thus the measurement period should be not greater than one third, of the paging duration. In order to reduce the battery power consumption caused by the SoC measurement as possible, preferably the measurement period is set as one third of the paging duration. Different Modem patterns have different paging durations, and the same Modem pattern may have several paging durations. Usually, the measurement period is set as one third of the minimum paging duration. This is because the SoC measurement will cover all of the durations only when the measurement period is defined as the minimum paging duration. Table 1 shows the relation between the paging duration and the measurement period in different Modem patterns.

TABLE 1

| | | Measurement |
|---|---|---|
| Modern Patterns | Paging Duration (s) | Period (s) |
| GSM | 0.472, 1.18, 2.124 | 0.472/3 |
| WCDMA&TD-SCDMA | 0.640, 1.28, 2.56, 5.12 | 0.640/3 |
| LTE | 0.32, 0.64, 1.28, 2.56 | 0.32/3 |
| Other devices | the minimum paging | Tₘᵢₙ/3 |
| | duration = Tₘᵢₙ | |

When the Modem is in a non-signaled environment, the paging duration may also be a fixed value. It may be longer than the paging duration, e.g., four paging durations or more. However, the result should meet the requirement of measurement accuracy (e.g., 1%).

The process of determining the measurement period is described in this embodiment by taking the Modem that is connected to the AP as an example. If that connected to the AP is a module such as a Bluetooth or WLAN module, the process similar to the above-mentioned steps may also be used to define the measurement period.

For the AP without Modem or other connection modules (e.g., in a flight mode), the battery of the mobile terminal will maintain a stable state when in the sleep or idle mode, without any voltage pulse response or paging duration. Therefore, the measurement period may be defined freely when the measurement accuracy is met.

Step 504: the working voltage values and the working current values of the battery are measured.

In general, the measurement of the battery parameters will increase the power consumption. Following is an example where PRCMU is used to read/write an AB8540 register on a STE platform so as to describe the increase in the power consumption. When the PRCMU reads/writes the AB8540 register to acquire the battery parameters, the power consumption is about 1 mA (when VBAT=3.8v), and the basic read/write duration is about 10 μs. When the mobile terminal is in a sleep/idle mode, the paging duration is about 1.28 s (when in a GSM network), and the maximum power consumption in this state is about 2.6 mA. Presumed that the parameter measurement is performed only once within a single paging duration, the Increased average current is about 0.0078 μA (i.e., 1000 Aμ*0.01 ms/1280 ms). So the increased idle current in the paging duration of 1.28 s may be ignored. Even if the measurement period is of a micro-second level, e.g., 100 ms, the increased current is about 0.1 μA (i.e., 0.0073 uA*1230 ms/100 ms), it may be ignored too. It can therefore be seen that, the power consumption due to the measurement of the battery parameters may be ignored.

Once the measurement period is determined, it is able to measure the working voltage and the working current of the mobile terminal in accordance with the measurement period. As shown in FIG. 4, the measurement is performed three limes within a paging duration, and three sampling points are obtained. The working current value and the working voltage value are obtained at each sampling point. The sampling point will be an invalid one if it is within the paging timeslot.

Step 505: whether the stored battery parameters exceed an upper limit is judged. If yes, it turns to Step 506, and if not, it proceeds to Step 507.

When the mobile terminal is in the sleep or idle mode, the device according to the present invention will acquire the working current values and the working voltage values all the time in accordance with the measurement period, and store the measured working current values and working voltage values in a RAM (Random Access Memory). If the RAM has limited storage space, it will turn to Step 506 when the storage space of the RAM is used up. Usually, the measurement values will not occupy too much of the storage space.

Step 506: the battery parameters are processed, e.g., the battery parameters stored in the RAM may be transferred to the other storage space, or some of the battery parameters acquired previously may be removed.

The storage space with a feed size may be defined to store the measurement values for a certain period of time in accordance with the actual situation. After being acquired, the measurement values may be stored in the storage space.

Step 507: the measured battery parameters are accessed when the mobile terminal exits the sleep or idle mode.

When the mobile terminal is awoken or exits the sleep or idle mode, the device accesses the battery parameters stored in the RAM. As shown in FIG. 4, when, the mobile terminal is in the sleep or idle mode, the working voltage of the battery will maintain at AV, decrease to BV within the paging timeslot, and maintain at AV again after the release point. The working current will maintain at YmA, increase to XmA within the paging timeslot, and maintain at YmA again after the paging timeslot. After being obtained at the sampling points, these measurement values may be filtered in accordance with a predetermined voltage threshold and a predetermined current threshold, and the working voltage values less than the predetermined voltage threshold and the working current values greater than the predetermined current threshold may be removed. In this embodiment, since the measurement values obtained within the paging timeslot are invalid, the voltage threshold, may be set as less than AV but greater than BV, and the current threshold may be set as less than XmA and greater than YmA, so it is able to filter the measurement values within the paging timeslot, and then the working voltage values not less than the voltage threshold and the working current values not greater than the current threshold are stored as the valid battery parameters.

For the Modem of a GSM, WCDMA/TD-SCDMA or LTE mode, an upper limit of IBAT should be greater than 40 mA, so the current threshold may be set as 40 mA, and the IBAT values greater than 40 mA in these modes will be regarded as invalid. For the other connection modules, the working current within the paging limes lot may be less than 40 mA, and the current threshold may be determined in accordance with the practical situation.

In addition, as shown in FIG. 4, a voltage alarm threshold is provided. When the working voltage is less than the voltage alarm threshold, it means that the working voltage is insufficient to maintain operation of the system of the mobile terminal and an alarm needs to be given.

Step 508: the battery power is calculated in accordance with the stored working voltage values and working current values, and a curve of battery power consumption is acquired.

Three main parameters are used to calculate the battery power, i.e., working voltage value, working current value and battery temperature. When the mobile terminal is in the sleep or idle mode, the battery temperature remains stable and may be acquired via a temperature sensor. After acquiring the battery temperature, it is able to calculate the current battery power of the mobile terminal (i.e., when the mobile terminal exits the sleep/idle mode) in accordance with the valid working voltage value and working current value stored last time. The battery power is measured with high accuracy through the technical solution of the present invention, and the difference from the actual battery power is less than 1%.

In addition, it is also able to obtain a curve of battery power consumption in accordance with all of the stored valid working voltage values and working current values when the mobile terminal is in the sleep/idle mode, thereby to obtain a process of the battery power consumption of the mobile terminal in the sleep or idle mode.

According to the embodiment of the present invention, after the mobile terminal enters the sleep/idle mode, the battery parameters are measured in accordance with the predetermined measurement period, so it is able to accurately obtain the SoC when the mobile terminal is in the sleep/idle mode. When the mobile terminal exits the sleep/idle mode, it is able to accurately calculate the battery power of the mobile terminal in accordance with the stored battery parameters. Especially, when the mobile terminal is in the sleep or idle mode for a long period of time, the measurement accuracy of the SoC of the mobile terminal can be increased according to the technical solution of the present invention.

The present invention further provides a mobile terminal comprising the above-mentioned device for measuring SoC. The mobile terminal can measure the battery parameters in accordance with a predetermined measurement period after it enters a sleep/idle mode, thereby to accurately acquire the SoC when the mobile terminal is in the sleep/idle mode. When the mobile terminal exits the sleep/idle mode, it is able to accurately calculate the battery power of the mobile terminal in accordance with the stored battery parameters. Especially, when the mobile terminal is in the sleep or idle mode for a long period of time, the measurement accuracy of the battery power of the mobile terminal can be increased according to the technical solution of the present invention.

The functional members described in the specification are referred to as modules, so as to emphasize the independence of the implementation in a more particular manner.

According to the embodiments of the present invention, the modules may be implemented by software, so as to be executed by various processors. For example, an identified, executable code module may comprise one or more physical or logical blocks including computer instructions, and the module can be constructed as an image, a process or a function. Even so, the executable codes of the identified modules are unnecessary to be physically located together, but may comprise different instructions stored in different locations. When these instructions are logically combined together, they form the modules and achieve the prescribed purposes of the modules.

Actually, the executable code module may be a single instruction or a plurality of instructions, and can even be distributed at different code segments, in different programs, or across a plurality of memory devices. Also, operational data may be identified in the modules, implemented in any appropriate form, and organized in any data structure of an appropriate type. The operational data may be collected as a single data set, or distributed at different locations (including different memory devices), and may be at least partially present in a system or network merely as an electronic signal.

When the modules can be implemented by software, considering the current hardware level, a person skilled in the art can build a corresponding hardware circuit to achieve the corresponding function if taking no account of the cost. The hardware circuit comprises a conventional very-large-scale integration (VLSI) circuit, a gate array, an existing semiconductor such as a logic chip and a transistor, or other discrete components. The modules may further be implemented by a programmable hardware device, such as a field-programmable gate array, a programmable array logic device or a programmable logic device.

In the embodiments of the present invention, the order of the steps is not limited to the serial numbers thereof. For a person skilled in the art, any change in the order of the steps also fall within the protection scope of the present invention if without any creative effort.

Those above are merely the embodiments of the present invention. It should be noted that, a person skilled in the art may further make improvements and modifications without departing from the principle of the present invention, and these improvements and modifications shall also be considered as the scope of the present invention.

What is claimed is:

1. A method for measuring state of charge of a mobile terminal, comprising:
measuring, after the mobile terminal enters a sleep/idle mode, battery parameters of the mobile terminal in accordance with a predetermined measurement period;
filtering, when the mobile terminal exits the sleep/idle mode, the measured battery parameters and storing the filtered battery parameters; and
acquiring state of charge of the mobile terminal in accordance with the stored battery parameters.

2. The method according to claim 1, wherein prior to measuring battery parameters of the mobile terminal in accordance with a predetermined measurement period, the method further comprises:
receiving a hardware indicator signal that indicates the mobile terminal to enter the sleep/idle mode.

3. The method according to claim 1, wherein the measurement period is not greater than one third of the minimum paging duration of the mobile terminal.

4. The method according to claim 1, wherein the battery parameters include working voltage values and working current values of the battery, and the step of filtering the measured battery parameters includes:
removing the working voltage values less than a predetermined voltage threshold and the working current values greater than a predetermined current threshold from the measured battery parameters; and
storing the working voltage values not less than the predetermined voltage threshold and the working current values not greater than the predetermined current threshold.

5. The method according to claim 4, wherein the step of acquiring state of charge of the mobile terminal in accordance with the stored battery parameters includes:
calculating the battery power in accordance with the stored battery parameters when the mobile terminal exits the sleep/idle mode, and acquiring a curve of the battery power consumption when the mobile terminal is in the sleep/idle mode.

6. The method according to claim 5, wherein the step of calculating the battery power in accordance with the stored battery parameters when the mobile terminal exits the sleep/idle mode includes:
calculating the battery power in accordance with the working voltage value and working current value stored last time when the mobile terminal exits the sleep/idle mode.

7. The method according to claim 5, wherein the step of acquiring a curve of the battery power consumption when the mobile terminal is in the sleep/idle mode includes:
calculating a curve of the battery power consumption in accordance with ail of the stored working voltage values and working current values when the mobile terminal is in the sleep/idle mode.

8. A device for measuring state of charge of a mobile terminal, comprising:
a measuring module, configured to measure, after the mobile terminal enters a sleep/idle mode, battery parameters of the mobile terminal in accordance with a predetermined measurement period;
a storing module, configured to filter, when the mobile terminal exits the sleep/idle mode, the measured battery parameters and store the filtered battery parameters; and
a calculating module, configured to acquire state of charge of the mobile terminal in accordance with the stored battery parameters.

9. The device according to claim 8, wherein the device further comprises:
a receiving module, configured to receive a hardware indicator signal that indicates the mobile terminal to enter the sleep/idle mode, wherein
the measuring module, configured to, after the receiving module receives the hardware indicator signal that indicates the mobile terminal to enter the sleep/idle mode, measure a plurality of battery parameters of the mobile terminal simultaneously in accordance with the predetermined measurement period.

10. The device according to claim 8, wherein the measurement period is not greater than one third of the minimum paging duration of the mobile terminal.

11. The device according to claim 8, wherein the battery parameters include working voltage values and working current values of the battery, and the storing module comprises:
a filtering submodule, configured to remove the working voltage values less than a predetermined voltage threshold and the working current values greater than a predetermined current threshold from the measured battery parameters; and
a storing submodule, configured to store the working voltage values not less than the predetermined voltage threshold and the working current values not greater than the predetermined current threshold.

12. The device according to claim 11, wherein the calculating module comprises:
a first calculating submodule, configured to calculate the battery power in accordance with the stored battery parameters when the mobile terminal exits the sleep/idle mode; and
a second calculating submodule, configured to acquire a curve of battery power consumption when the mobile terminal is in the sleep/idle mode.

13. The device according to claim 12, wherein
the first calculating submodule, configured to calculate the battery power in accordance with the working voltage value and the working current value stored last time when the mobile terminal exits the sleep/idle mode.

14. The device according to claim 12, wherein
the second calculating submodule, configured to calculate a curve of battery power consumption in accordance with all of the stored working voltage values and working current values when the mobile terminal is in the sleep/idle mode.
